(19) United States
(12) Patent Application Publication
(10) Pub. No.: US 2026/0107798 A1
(43) Pub. Date: Apr. 16, 2026

(54) SEMICONDUCTOR PACKAGE DEVICE AND PACKAGE SUBSTRATE THEREOF

(71) Applicants: GLOBAL UNICHIP CORPORATION, HSINCHU CITY (TW); TAIWAN SEMICONDUCTOR MANUFACTURING COMPANY, LTD., Hsinchu (TW)

(72) Inventors: Yao-Tsu CHEN, HSINCHU CITY (TW); Sheng-Fan YANG, HSINCHU CITY (TW); Chi-Lou YEH, HSINCHU CITY (TW); Chung-Hsuan WU, HSINCHU CITY (TW)

(21) Appl. No.: 18/988,797

(22) Filed: Dec. 19, 2024

(30) Foreign Application Priority Data
Oct. 16, 2024 (TW) 113139312

(51) Int. Cl. H01L 23/498; H01L 23/00

(52) U.S. Cl. CPC H10W 70/65; H10W 70/685; H10W 90/724

(57) ABSTRACT

A package substrate comprises a solder mask layer, a composite layer, a ground layer, and a signal layer. Multiple power contacts, multiple ground contacts, multiple first signal contacts, and multiple second signal contacts are arranged on the solder mask layer. Multiple power planes and multiple first signal routings are arranged on the composite layer. The power planes are correspondingly coupled to the power contacts. The first signal routings are correspondingly coupled to the first signal contacts. A ground line is arranged on the ground layer. The ground line is coupled to the ground contacts. Multiple second signal routings are arranged on the signal layer. The second signal routings are correspondingly coupled to the second signal contacts.

### RELATED APPLICATION

This application claims priority to Taiwan Application Serial Number 113139312, filed October 16, 2024, which is herein incorporated by reference.

### BACKGROUND

### Field of the Invention

The present disclosure relates to a semiconductor package device and a package substrate thereof, and in particular, to a semiconductor package device and a package substrate having high-frequency noise decoupling capabilities.

### Description of the Related Art

Communication system chips, such as communication system chips with high-speed SerDes, are prone to generate simultaneous switching noises (SSNs) under high-frequency operation. SSN may affect the power supply quality of the chip when being transmitted through a power network in a package substrate, thereby affecting the communication quality of the chip.

In the prior art, a decoupling capacitor is usually arranged on the package substrate to reduce the impact of SSN on the chip that is also arranged on the package substrate. However, the configuration of the decoupling capacitor will increase processing costs and material costs. In addition, the decoupling capacitor needs to be electrically connected to the chip through the package substrate. Such a configuration may affect the effect of the decoupling capacitor.

Therefore, developing a novel semiconductor package device that can reduce SSN is an important issue in the field of high-speed communications.

### SUMMARY

One aspect of the present disclosure is a package substrate, which comprises a solder mask layer, a composite layer, a ground layer, and a signal layer. Multiple power contacts, multiple ground contacts, multiple first signal contacts, and multiple second signal contacts are arranged on the solder mask layer. Multiple power planes and multiple first signal routings are arranged on the composite layer. The power planes are correspondingly coupled to the power contacts. The first signal routings are correspondingly coupled to the first signal contacts. A ground line is arranged on the ground layer. The ground line is coupled to the ground contacts. Multiple second signal routings are arranged on the signal layer. The second signal routings are correspondingly coupled to the second signal contacts.

Another aspect of the present disclosure is a semiconductor package device, which comprises a package substrate and a chip. The package substrate comprises a solder mask layer, a composite layer, a ground layer, and a signal layer. Multiple power contacts, multiple ground contacts, multiple first signal contacts, and multiple second signal contacts are arranged on the solder mask layer. Multiple power planes and multiple first signal routings are arranged on the composite layer. The power planes are correspondingly coupled to the power contacts. The first signal routings are correspondingly coupled to the first signal contacts. A ground line is arranged on the ground layer. The ground line is coupled to the ground contacts. Multiple second signal routings are arranged on the signal layer. The second signal routings are correspondingly coupled to the second signal contacts. The chip is coupled to the package substrate.

### BRIEF DESCRIPTION OF THE DRAWINGS

The present disclosure may be more fully understood by reading the following detailed description of the embodiments with reference to the following drawings.

FIG. 1 is a schematic diagram of a semiconductor package device in accordance with some embodiments of the present disclosure.

FIG. 2 is a three-dimensional schematic view of a package substrate in accordance with some embodiments of the present disclosure.

FIG. 3 is a top view of a package substrate in accordance with some embodiments of the present disclosure.

FIG. 4 is a schematic diagram of a connection method between a package substrate and a chip in accordance with some embodiments of the present disclosure.

### DETAILED DESCRIPTION

The following is a detailed description of embodiments in conjunction with the accompanying drawings, but the specific embodiments described are only used to explain the present application and are not used to limit the present application, and the description of structural operations is not intended to limit the order of execution. Any structure that is reassembled of components to produce a device with equal functions is within the scope of the present disclosure.

The terms used throughout the specification and the claims of the present application, unless otherwise noted, usually have the ordinary meaning of each term used in this field, in the content disclosed here, and in the special content.

In addition, for convenience of description, spatially relative terms (e.g., “over”, “covering”, “on”, “upper”, “top”, “under”, “under a surface”, “below”, “beneath”, “lower”, “bottom”, “side”, and the like) may be used herein to describe the relationship of one element or feature to another (other) element(s) or feature(s) as illustrated in the drawings. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

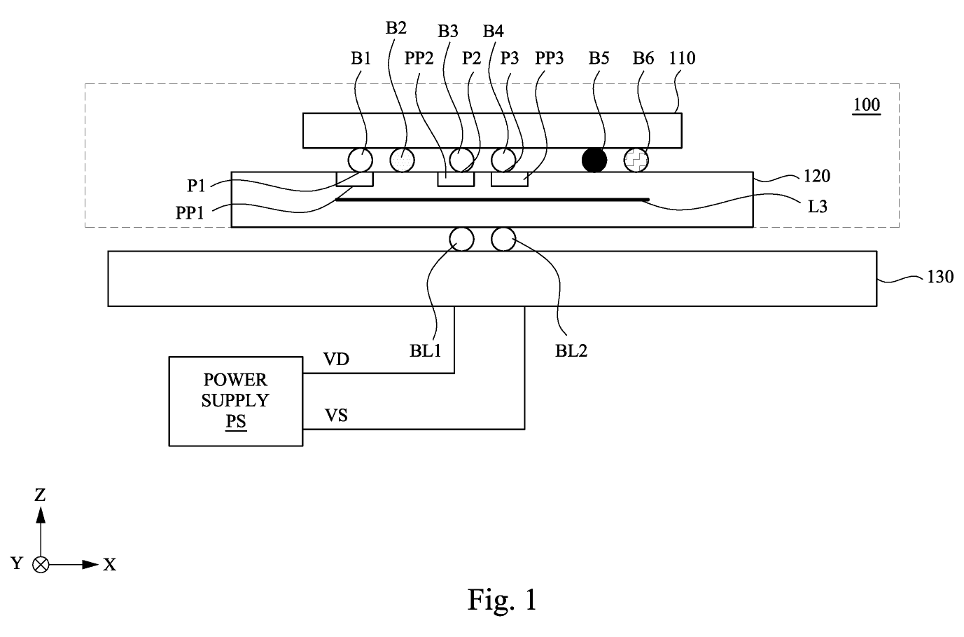

Please refer to FIG. 1. FIG. 1 is a schematic diagram of a semiconductor package device 100 in accordance with some embodiments of the present disclosure. As shown in FIG. 1, the semiconductor package device 100 comprises a chip 110 and a package substrate 120. The chip 110 is electrically connected to the package substrate 120 through bumps B1-B12, wherein the bumps B7-B12 are respectively located behind the bumps B1-B6 (not shown in the figure for the sake of simplicity). In addition, the package substrate 120 is electrically connected to a printed circuit board 130 through conductive balls BL1-BL2. The printed circuit board 130 is configured to electrically connect a power supply PS. As such, the chip 110 can receive power from the power supply PS through the package substrate 120 and the printed circuit board 130.

Specifically, the power output by the power supply PS is sequentially transmitted to the chip 110 through the printed circuit board 130, the conductive balls BL1-BL2, the package substrate 120 and a portion of the bumps B1-B12. In some embodiments, the power supply may be a power supply voltage VD and a reference voltage VS. In some embodiments, the power supply voltage VD is 0.75 volts. In some embodiments, the reference voltage VS is ground voltage (i.e., 0 volts).

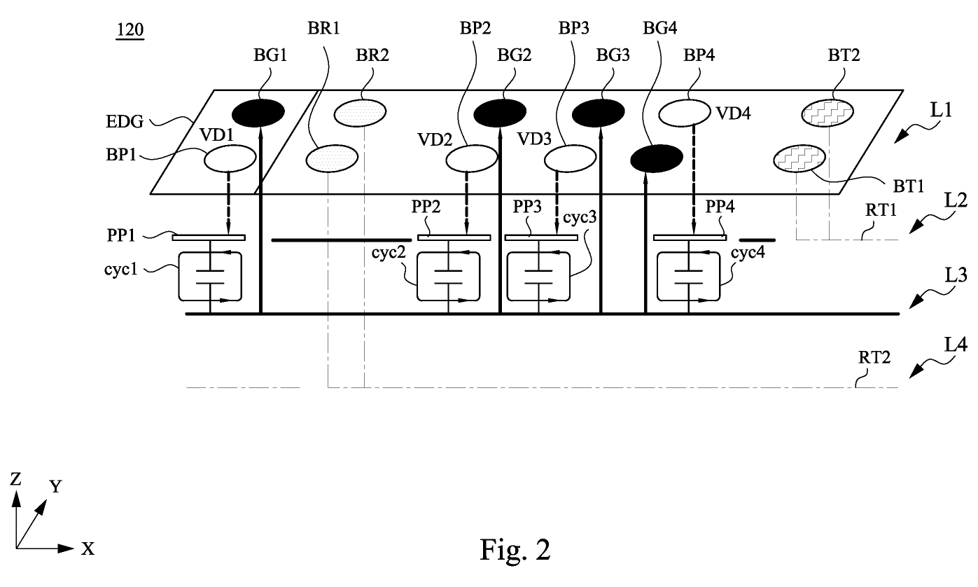

Please refer to FIG. 2. FIG. 2 is a three-dimensional schematic view of a package substrate 120 in accordance with some embodiments of the present disclosure. As shown in FIG. 2, the package substrate 120 is a multi-layer structure. Specifically, the package substrate 120 comprises a solder mask layer L1, a composite layer L2, a ground layer L3, and a signal layer L4. Each of the solder mask layer L1, the composite layer L2, the ground layer L3, and the signal layer L4 forms a plane along a direction X and a direction Y, and these planes are vertically arranged along a direction Z. In some embodiments, the direction X and the direction Y are perpendicular to each other. In addition, the composite layer L2 and the ground layer L3 are disposed between the solder mask layer L1 and the signal layer L4, and positions of the composite layer L2 and the ground layer L3 may be adjusted according to design requirements. In some embodiments, as shown in FIG. 2, the ground layer L3 is disposed beneath the composite layer L2. In other words, the composite layer L2 is disposed between the solder mask layer L1 and the ground layer L3. As such, the solder mask layer L1, the composite layer L2, the ground layer L3 and the signal layer L4 in the package substrate 120 are stacked in sequence from top to bottom. In some embodiments, the composite layer L2 is disposed beneath the ground layer L3. In other words, the ground layer L3 is disposed between the solder mask layer L1 and the composite layer L2. As such, the solder mask layer L1, the ground layer L3, the composite layer L2 and the signal layer L4 in the package substrate 120 are stacked in sequence from top to bottom.

Please refer to FIG. 1 and FIG. 2. The solder mask layer L1 is a surface layer of the package substrate 120 and comprises a plurality of contacts BP1-BP4, BG1-BG4, BR1-BR2, and BT1-BT2, which are configured to correspondingly electrically connect the bumps B1-B12. Specifically, the contacts BP1-BP4 are electrically connected to the bumps B1, B3, B4 and B11, respectively. The contacts BG1-BG4 are electrically connected to the bumps B7, B9, B10 and B5, respectively. The contacts BR1-BR2 are electrically connected to the bumps B2 and B8, respectively. The contacts BT1-BT2 are electrically connected to the bumps B6 and B12, respectively. In some embodiments, these contacts BP1-BP4, BG1-BG4, BT1-BT2, and BR1-BR2 are implemented by bump pads, in which the contacts BP1-BP4 may be regarded as power contacts; the contacts BG1-BG4 may be regarded as ground contacts; the contacts BR1-BR2 and the contacts BT1-BT2 may be regarded as two different signal contacts.

In addition, according to actual design requirements, a portion of the power contacts of the solder mask layer L1 may be disposed between the two different signal contacts, and another portion thereof may be disposed between one of the signal contacts and an edge of the solder mask layer L1. For example, the power contacts BP2-BP4 are arranged between the signal contacts BR1-BR2 and the signal contacts BT1-BT2. The power contact BP1 is arranged between the signal contacts BR1-BR2 and an edge EDG of the solder mask layer L1.

Refer again to FIG. 2. The power contacts BP1-BP4 appear in pairs with the ground contacts BG1-BG4, respectively; the signal contact BR1 appears in a pair with the signal contact BR2; and the signal contact BT1 appears in a pair with the signal contact BT2. These contact pairs are arranged in sequence along the direction X. Specifically, the contact pair formed by the power contact BP1 and the ground contact BG1, the contact pair formed by the power contact BP2 and the ground contact BG2, the contact pair formed by the power contact BP3 and the ground contact BG3, the contact pair formed by the power contact BP4 and the ground contact BG4, and the contact pair formed by the signal contact BT1 and the signal contact BT2 are arranged along the direction X in sequence. In some embodiments, the two contacts of the contact pair may be arranged in a direction different from the direction X. For example, the power contact BP1 and the ground contact BG1 may be arranged at an angle of 45 degrees, 90 degrees, 135 degrees, 225 degrees, or 315 degrees to the direction X.

In conjunction with FIG. 1, please refer to FIG. 2. The power supply PS generates multiple power supply voltages VD1-VD4 and a reference voltage VS, and the multiple power supply voltages VD1-VD4 and the reference voltage VS are respectively transmitted to the chip 110 through the contact pairs formed by the power contacts BP1-BP4 and the ground contacts BG1-BG4. As such, the chip 110 can obtain different power supply voltages through the contact pairs formed by the power contacts BP1-BP4 and the ground contacts BG1-BG4. In addition, the chip 110 can communicate with a remote device through the contact pairs formed by the signal contacts BR1-BR2 and the signal contacts BT1-BT2.

In some embodiments, a digital circuit in the chip 110 obtains power supply requirements through the contact pair formed by the power contact BP1 and the ground contact BG1. An analog circuit in the chip 110 obtains power supply requirements through the contact pairs formed by the power contacts BP2-BP4 and the ground contacts BG2-BG4. Furthermore, the solder mask layer L1 can determine a number of the contact pairs formed by the power contacts and the ground contacts according to actual design requirements.

Refer again to FIG. 1 and FIG. 2. The composite layer L2 is disposed beneath the solder mask layer L1 and comprises a plurality of power planes and a plurality of signal routings RT1. A number of the power planes in the composite layer L2 may be less than or equal to a number of the power contacts in the solder mask layer L1.

The composite layer L2 comprises four power planes PP1-PP4, and each of the power planes PP1-PP4 are arranged separately from each other. The power planes PP1-PP4 may be conductive metal planes. At the same time, the power planes PP1-PP4 are respectively arranged beneath the power contacts BP1-BP4 along the direction Z and are electrically connected to lower surfaces of the power contacts BP1-BP4, respectively, where the direction Z is perpendicular to the direction X and the direction Y. Furthermore, according to actual design requirements, an orthographic projection of one of the power planes PP1-PP4 is overlapped or partially overlapped with one of the power contacts BP1-BP4.

According to actual design requirements, a number of the power planes may be equal to a number of the power contacts, wherein the power planes may be coupled to the power contacts in a one-to-one relationship. For example, the power planes PP1-PP4 may be electrically coupled to the power contacts BP1-BP4, respectively. In addition, according to actual design requirements, a number of the power planes may be smaller than a number of the power contacts. Under this design, the power planes may be coupled to the power contacts in a one-to-many relationship. Alternatively, a first portion of the power planes are coupled to a first portion of the power contacts in a one-to-one relationship, and a second portion of the power planes are coupled to a second portion of the power contacts in a one-to-many relationship. For example, only the power planes PP1 and PP3 are arranged in the composite layer L2, wherein the power plane PP1 is electrically coupled to the power contact BP1, and the power plane PP3 is electrically coupled to the power contacts BP2-BP4. Refer again to FIG. 2. The ground contacts BG1-BG4 of the solder mask layer L1 are electrically connected to a ground line of the ground layer L3. At the same time, each of the power planes PP1-PP4 of the composite layer L2 respectively form corresponding interlayer capacitors with the ground layer L3, and the power planes PP1-PP4 are end points of the interlayer capacitors, respectively.

The aforementioned interlayer capacitor may be used as a decoupling capacitor to reduce the impact of SSN noise on power supply quality of the chip 110 and maintain good signal transmission quality.

Specifically, the power plane PP1, the power contact BP1, the ground contact BG1 and the ground layer L3 can form a power distribution network (PDN) having the decoupling capacitor with the chip 110 to provide power to the chip 110. Similarly, the power planes PP2-PP4, the power contacts BP2-BP4, the ground contacts BG2-BG4, and the ground layer L3 can form another power distribution network having the decoupling capacitor with the chip 110 to supply power to the chip 110. As such, four decoupling capacitors formed by the power planes PP1-PP4 and the ground layer L3 are disposed in a dispersed manner and provide shorter decoupling loops cyc1-cyc4 in each corresponding power distribution network to reduce the impact of SSN noise on each power distribution network, so as to ensure power supply quality and signal transmission quality of the chip 110. Compared with the method of arranging decoupling capacitors outside the package substrate, the present disclosure uses the interlayer capacitors to achieve decoupling, which can save processing costs and material costs. At the same time, the interlayer capacitors are more closely connected to the chip 110 through the power contacts to provide better decoupling effect.

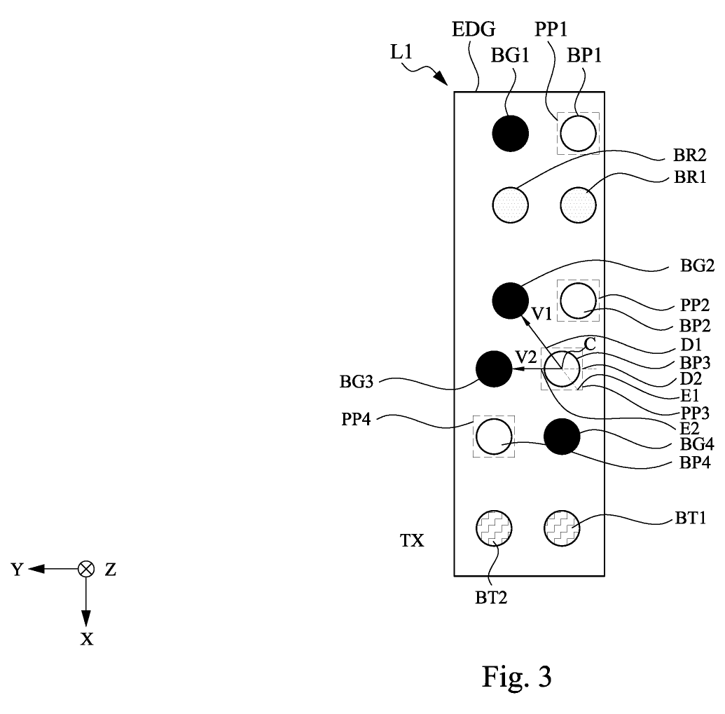

In conjunction with FIG. 2, please refer to FIG. 3. FIG. 3 is a top view of a package substrate 120 in accordance with some embodiments of the present disclosure. The placement angle and size of the power planes in the composite layer L2 may be designed according to actual needs. In some embodiments, positions of the multiple contacts on the solder mask layer L1 are equidistantly arranged. At this time, a side length of each of the power planes in the composite layer L2 is greater than 1/6 times a distance between two adjacent contacts, so that a generated capacitance value is enough to fully reduce the impact of SSN noise on power supply quality, thereby maintaining good signal transmission quality. Specifically, the distance between the contacts is a distance between center points of the two contacts.

In some embodiments, a size of the power plane that can achieve optimal decoupling is determined based on the distance between the adjacent contacts. The maximum size that keeps the power planes being separated from each other can allow semiconductor package device 100 for optimal decoupling. Here, “adjacent contacts” refer to contacts closest to each other in each direction (0 degrees to 360 degrees). For example, contacts adjacent to the contact BP3 are the contacts BP2, BG2, BG3, BP4, and BG4.

Similarly, the direction is also defined based on the center point. For example, a direction of the contact BP2 with respect to/relative to the contact BP3 is a direction from the center point of the contact BP3 to the contact BP2 (i.e., an arrangement direction of the contact BP2 and the contact BP3).

The following takes the power plane PP3 as an example to illustrate how to determine the size of the power plane (this is only an example and is not intended to limit the present disclosure). In some embodiments, the size of power plane PP3 is determined by a distance between the contact BP3 and the contact BG2. As shown in FIG. 3, the contacts BP3 and BG2 are arranged along a direction V1, and the power plane PP3 has a center point C. A cut edge length that the power plane PP3 passes through the center point C along the direction V1 (i.e., a distance between a point D1 and a point E1) is at least less than 2 times the distance between the contact BP3 and the contact BG2, wherein the point D1 and the point E1 are two points where a straight line passing through the center point C along the direction V1 intersects edges of the power plane PP3. If a side length of the power plane PP3 is along the direction V1 (i.e., parallel to the direction V1), the above-mentioned cut edge length is equal to the side length.

In some embodiments, the power planes are arranged in the same direction (e.g., the power planes extend along the direction X and the direction Y), and the contacts are arranged equidistantly along the direction X and along the direction Y. Correspondingly, the restriction on sizes of the power planes PP1-PP4 is: the side length of the power plane PP1, PP2, PP3, or PP4 is at least less than 2 times the distance between two adjacent contacts.

In some embodiments, the size of the power plane PP3 is determined by a distance between the contact point BP3 and the contact point BG3. As shown in FIG. 3, the contact BP3 and the contact BG3 are arranged along a direction V2, and a cut edge length that the power plane PP3 passes through the center point C along the direction V2 (i.e., a distance between a point D2 and a point E2) is at least less than 2 times the distance between the contact BP3 and the contact BG3, wherein the point D2 and the point E2 are two points where a straight line passing through the center point C along the direction V2 intersects edges of the power plane PP3. If a side length of the power plane PP3 is along the direction V2, the above-mentioned cut edge length is equal to the side length.

In addition, in some embodiments, for a specific power plane, the size of the specific power plane may be determined based on at least two distances between adjacent contacts. For example, for the power plane PP3, in addition to the above-mentioned distance between the contact BP3 and the contact BG2, the size of the power plane PP3 is also determined based on the distance between the contact BP3 and the contact BG3. In other words, the size of the power plane PP3 satisfies the following conditions: the cut edge length that the power plane PP3 passes through the center point C along the direction V1 is at least less than 2 times the distance between the contact BP3 and the contact BG2, and the cut edge length that the power plane PP3 passes through the center point C along the direction V2 is at least less than 2 times the distance between the contact BP3 and the contact BG3. If a first side length of the power plane PP3 is along the direction V1 and a second side length of the power plane PP3 is along the direction V2, the cut edge length of the power plane PP3 along the direction V1 through the center point C is equal to the first side length, and the cut edge length of the power plane PP3 along the direction V2 through the center point C is equal to the second side length.

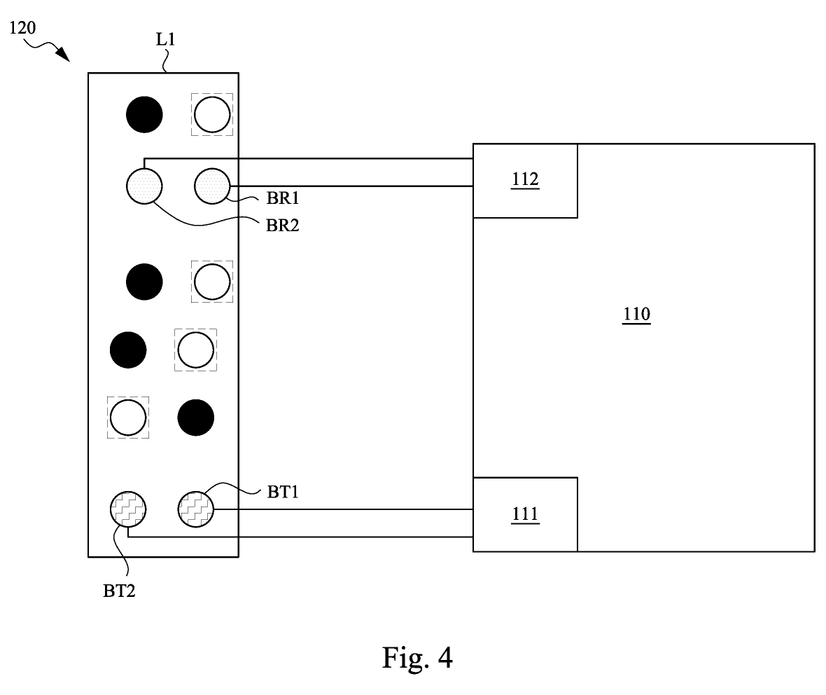

Please refer to FIG. 1, FIG. 2 and FIG. 4 together. FIG. 4 is a schematic diagram of a connection method between a package substrate 120 and a chip 110 in accordance with some embodiments of the present disclosure. As shown in FIG. 4, the package substrate 120 is electrically connected to a transmitter 111 and a receiver 112 in the chip 110 through the solder mask layer L1. Specifically, the transmitter 111 and the receiver 112 in FIG. 4 are disposed in SerDes IP in the chip 110. In some embodiments, the chip 110 may comprise a plurality of SerDes IPs. Correspondingly, the solder mask layer L1 of the package substrate 120 is electrically connected to the transmitter 111 and the receiver 112 in the SerDes IP through the signal contacts BT1, BT2, BR1 and BR2. In addition, the SerDes IP may be a new generation of high-speed connection interface such as PCI-E, SATA 2 and USB 3.0.

Please refer to FIG. 2 and FIG. 4. According to an embodiment, the signal contacts BT1 and BT2 of the solder mask layer L1 are electrically connected to the transmitter 111 of the chip 110 and the signal routing RT1 in the composite layer L2. As such, a transmission signal of the chip 110 may be transmitted to the remote device through the signal routing RT1 in the composite layer L2. At the same time, the signal contacts BR1 and BR2 of the solder mask layer L1 are electrically connected to the receiver 112 of the chip 110 and the signal routing RT2 in the signal layer L4. As such, the chip 110 can receive signals from the remote device through the signal routing RT2 in the signal layer L4. Furthermore, by changing the wire coupling manner, the transmission signal of the chip 110 may also be transmitted to the remote device through the signal routing RT2 in the signal layer L4, and signals are received from the remote device through the signal routing RT1 in the composite layer L2.

In summary, the present disclosure uses the interlayer capacitors in the package substrate 120 as the decoupling capacitors to effectively reduce the impact of SSN noise on power supply quality during chip operation, while maintaining good signal transmission quality of the chip 110. In addition, by replacing the external decoupling capacitor with the interlayer capacitor in the package substrate 120, normal characteristics of the chip may be maintained, and processing costs and material costs may be reduced. However, it should be understood that although the present disclosure is provided to solve the performance problem of serializers, the application of the present disclosure is not limited thereto. All applications through the technical means of the present disclosure shall fall within the scope of protection of the present disclosure.

Although the present disclosure has been disclosed in the above embodiments, it is not intended to limit the present disclosure, and it is to be understood that those skilled in the art can make various changes and modifications without departing from the spirit and scope of the present disclosure. The scope of protection of the present disclosure is subject to the scope of appended claims.

What is claimed is:

1. A package substrate, comprising:
a solder mask layer, on which a plurality of power contacts, a plurality of ground contacts, a plurality of first signal contacts and a plurality of second signal contacts are arranged;
a composite layer, on which a plurality of power planes and a plurality of first signal routings are arranged, wherein the plurality of power planes are correspondingly coupled to the plurality of power contacts, and the plurality of first signal routings are correspondingly coupled to the plurality of first signal contacts;
a ground layer, on which a ground line is arranged, wherein the ground line is coupled to the plurality of ground contacts; and
a signal layer, on which a plurality of second signal routings are arranged, wherein the plurality of second signal routings are correspondingly coupled to the plurality of second signal contacts.

2. The package substrate of claim 1, wherein the plurality of power planes are conductive metal planes and are separately disposed in the composite layer.

3. The package substrate of claim 1, wherein the solder mask layer, the composite layer, the ground layer and the signal layer are stacked in sequence from top to bottom.

4. The package substrate of claim 1, wherein the solder mask layer, the ground layer, the composite layer and the signal layer are stacked in sequence from top to bottom.

5. The package substrate of claim 1, wherein a number of the plurality of power planes is equal to a number of the plurality of power contacts.

6. The package substrate of claim 5, wherein the plurality of power planes are coupled to the plurality of power contacts in a one-to-one relationship.

7. The package substrate of claim 1, wherein a number of the plurality of power planes is less than a number of the plurality of power contacts.

8. The package substrate of claim 7, wherein the plurality of power planes are coupled to the plurality of power contacts in a one-to-many relationship.

9. The package substrate of claim 7, wherein a first portion of the plurality of power planes are coupled to a first portion of the plurality of power contacts in a one-to-one relationship, and a second portion of the plurality of power planes are coupled to a second portion of the plurality of power contacts in a one-to-many relationship.

10. The package substrate of claim 1, wherein an orthographic projection of one of the plurality of power planes is overlapped with one of the plurality of power contacts.

11. The package substrate of claim 1, wherein an orthographic projection of one of the power planes is partially overlapped with one of the power contacts.

12. The package substrate of claim 1, wherein a first portion of the plurality of power contacts are disposed between the plurality of first signal contacts and the plurality of second signal contacts, and a second portion of the plurality of power contacts are disposed between the plurality of second signal contacts and an edge of the solder mask layer.

13. The package substrate of claim 1, wherein a distance between adjacent contacts of the plurality of power contacts and the ground plurality of contacts are the same, and each side length of one of the plurality of power planes is greater than 1/6 times the distance between the adjacent contacts.

14. The package substrate of claim 1, wherein a first power plane coupled to a first power contact of the plurality of power contacts has a cut edge length at least less than 2 times a distance between the first power contact and any adjacent one of the power contact or the ground contact arranged along a direction, wherein the cut edge length is a length between two points where a straight line passing through a center point of the first power plane intersects two edges of the first power plane.

15. A semiconductor package device, comprising:
a package substrate, comprising:
a solder mask layer, on which a plurality of power contacts, a plurality of ground contacts, a plurality of first signal contacts and a plurality of second signal contacts are arranged;
a composite layer, on which a plurality of power planes and a plurality of first signal routings are arranged, wherein the plurality of power planes are correspondingly coupled to the plurality of power contacts, and the plurality of first signal routings are correspondingly coupled to the plurality of first signal contacts;
a ground layer, on which a ground line is arranged, wherein the ground line is coupled to the plurality of ground contacts; and
a signal layer, on which a plurality of second signal routings are arranged, wherein the plurality of second signal routings are correspondingly coupled to the plurality of second signal contacts; and
a chip, coupled to the package substrate.

16. The semiconductor package device of claim 15, wherein the chip is coupled to the plurality of power contacts, the plurality of ground contacts, the plurality of first signal contacts and the plurality of second signal contacts through a plurality of bumps correspondingly.

17. The semiconductor package device of claim 15, wherein the chip comprises a SerDes IP provided with a transmitter and a receiver.

18. The semiconductor package device of claim 17, wherein the transmitter is coupled to the plurality of first signal contacts, and the receiver is coupled to the plurality of second signal contacts.

19. The semiconductor package device of claim 17, wherein the transmitter is coupled to the plurality of second signal contacts, and the receiver is coupled to the plurality of first signal contacts.
